(19) United States
(12) Patent Application Publication
(10) Pub. No.: US 2021/0233868 A1
(43) Pub. Date: Jul. 29, 2021

(54) SEMICONDUCTOR DEVICE PACKAGE AND METHOD FOR MANUFACTURING THE SAME

(71) Applicant: Advanced Semiconductor Engineering, Inc., Kaohsiung (TW)

(72) Inventor: Jenchun CHEN, Kaohsiung (TW)

(73) Assignee: Advanced Semiconductor Engineering, Inc., Kaohsiung (TW)

(21) Appl. No.: 16/774,135

(22) Filed: Jan. 28, 2020

(51) Int. Cl. H01L 23/00; H01L 23/31; H01L 23/29; H01L 23/13; H01L 23/498; H01L 21/48; H01L 21/56

(52) U.S. Cl. CPC H01L 23/562; H01L 23/3128; H01L 23/295; H01L 21/565; H01L 23/49838; H01L 21/4853; H01L 23/13

(57) ABSTRACT

A semiconductor device package and method of manufacturing the same are provided. The semiconductor device package includes a substrate, a semiconductor die and a first encapsulant. The substrate includes a first surface, a second surface opposite to the first surface, and a first edge and a second edge connecting the first surface to the second surface. The first edge is shorter than the second edge. The semiconductor die is disposed on the first surface of the substrate. The first encapsulant is disposed on the first surface of the substrate and encapsulates the semiconductor die. The first encapsulant includes at least one first lock portion extending from the first surface to the second surface and penetrating through the substrate via the first edge.

### BACKGROUND

### 1. Technical Field

The present disclosure relates to a semiconductor device package and method for manufacturing the same, and more particularly, to a semiconductor device package with compact side and high reliability and method for manufacturing the same.

### 2. Description of the Related Art

There is a continuing desire to incorporate multiple semiconductor components or electronic components into a semiconductor device package to reduce dimensions of the package. The margin between the component and the substrate edge needs to be shrunk to further reduce the size of the semiconductor device package. However, the shrinkage may cause delamination issue and thus affects the reliability.

### SUMMARY

In some embodiments, a semiconductor device package includes a substrate, a semiconductor die and a first encapsulant. The substrate includes a first surface, a second surface opposite to the first surface, and a first edge and a second edge connecting the first surface to the second surface. The first edge is shorter than the second edge. The semiconductor die is disposed on the first surface of the substrate. The first encapsulant is disposed on the first surface of the substrate and encapsulates the semiconductor die. The first encapsulant includes at least one first lock portion extending from the first surface to the second surface and penetrating through the substrate via the first edge.

In some embodiments, a semiconductor device package includes a substrate, a semiconductor die, a first encapsulant and a circuit board. The substrate includes a first surface, a second surface opposite to the first surface, and an edge connecting the first surface to the second surface. The semiconductor die is disposed on the first surface of the substrate. The first encapsulant is disposed on the first surface of the substrate and encapsulates the semiconductor die. The first encapsulant includes a plurality of lock portions each including an upper portion disposed on the first surface, a bottom portion disposed on the second surface, and a latch portion connected to the upper portion and the bottom portion and penetrating through the edge. Two adjacent bottom portions of the latch portions are separated with a spacing. The circuit board is disposed under the substrate, and the circuit board includes a surface facing the second surface of the substrate. The second encapsulant is disposed between the surface of the circuit board and the second surface of the substrate, and fills in the spacing.

In some embodiments, a method of manufacturing a semiconductor device package includes the following operations. A substrate is provided. The substrate includes a first surface, a second surface opposite to the first surface, and a plurality of through holes. A first encapsulant is formed on the substrate. The first encapsulant includes an upper portion on the first surface, a plurality of latch portions in the through holes, and a plurality of bottom portions on the second surface. The bottom portions are arranged along an arrangement direction, and adjacent bottom portions are separated with a spacing. a flow-able encapsulating material with fillers is introduced through the spacing of the bottom portions along a flow direction substantially perpendicular to the arrangement direction to form a second encapsulant on the second surface of the substrate.

### BRIEF DESCRIPTION OF THE DRAWINGS

Aspects of some embodiments of the present disclosure are readily understood from the following detailed description when read with the accompanying figures. Various structures may not be drawn to scale, and the dimensions of the various structures may be arbitrarily increased or reduced for clarity of discussion.

FIG. 1 is a schematic panoramic view of a semiconductor electronic device package in accordance with some embodiments of the present disclosure.

FIG. 1A is a schematic side view of a semiconductor device package from a short side in FIG. 1.

FIG. 1B is a schematic side view of a semiconductor device package from a long side in FIG. 1.

FIG. 1C is a schematic bottom view of a semiconductor device package in accordance with some embodiments of the present disclosure.

FIG. 1D is a schematic side view of a semiconductor device package in the absence of an encapsulation layer in accordance with some embodiments of the present disclosure.

FIG. 1E is a schematic bottom view of a semiconductor device package in the absence of an encapsulant layer in accordance with some embodiments of the present disclosure.

FIG. 2 is a schematic side view of a semiconductor device package in accordance with some embodiments of the present disclosure.

FIG. 3 is a schematic side view of a semiconductor device package in accordance with some embodiments of the present disclosure.

FIG. 4 is a schematic panoramic view of a semiconductor electronic device package in accordance with some embodiments of the present disclosure.

FIG. 4A is a schematic side view of a semiconductor device package from a long side in FIG. 4.

FIG. 4B is a schematic bottom view of a semiconductor device package in accordance with some embodiments of the present disclosure.

FIG. 4C is a schematic bottom view of a semiconductor device package in the absence of an encapsulant layer in accordance with some embodiments of the present disclosure.

FIG. 5 is a schematic side view of a semiconductor device package in accordance with some embodiments of the present disclosure.

FIG. 5A is a schematic bottom view of a semiconductor device package in accordance with some embodiments of the present disclosure.

FIG. 6 is a schematic side view of a semiconductor device package from a long side in accordance with some embodiments of the present disclosure.

FIG.7A, FIG.7B, FIG. 7C, FIG. 7D, FIG. 7E, FIG. 7F and FIG. 7G illustrate operations of manufacturing a semiconductor device package in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Fabrication of a semiconductor device package includes stacking a plurality of layers, components or semiconductor die in a variety of processes. Many of the processes are performed at high temperature. In addition, reliability test will be performed on the semiconductor device package by alternately placing the semiconductor device package at high temperature and low temperature environments. Accordingly, warpage may occur to the semiconductor device package. The warpage may further result in delamination, particularly on the short edge of the semiconductor device package which has the maximum deformation. The delamination makes it difficult to reduce the margin between the edge of the substrate and the semiconductor die, and thus the size of the semiconductor device package cannot be further reduced. To address the above issue, some embodiments of the present disclosure provide semiconductor device packages with lock portions that can firmly interlock with the substrate and tightly hold the semiconductor die. As a result, delamination can be alleviated, and the margin between the edge of the substrate and the semiconductor die can be further reduced. In addition, the adjacent lock portions may be separated by a spacing larger than filler size of an encapsulant such that the lock portions do not adversely affect mold flow of the encapsulant.

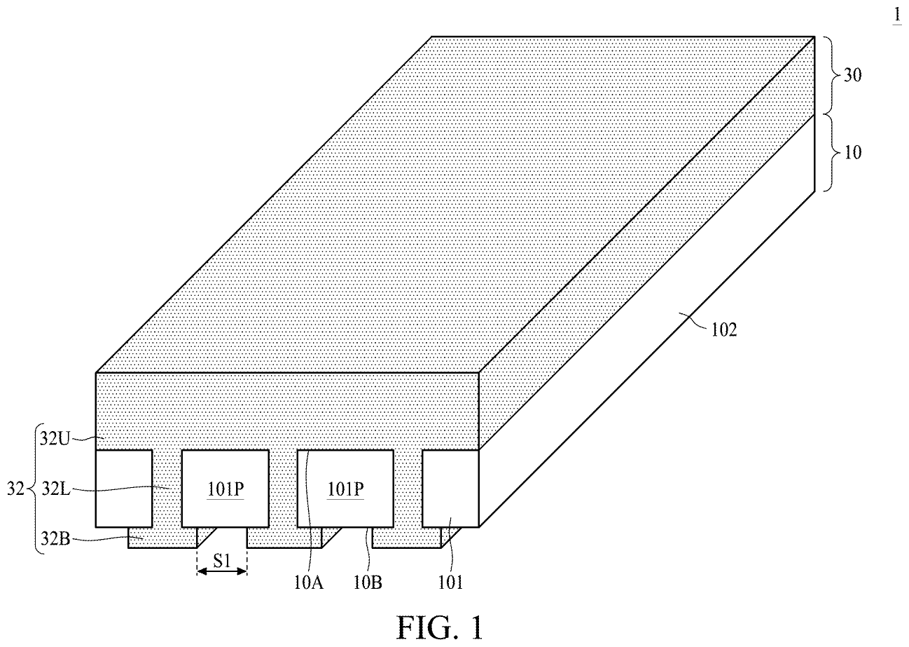

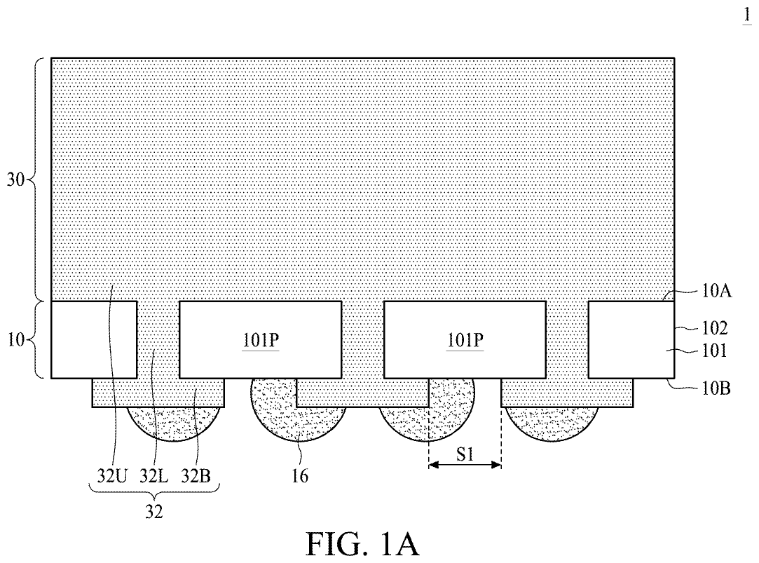

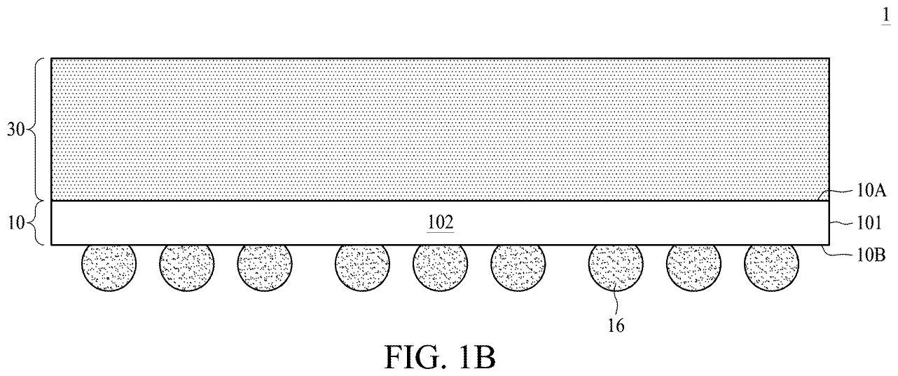

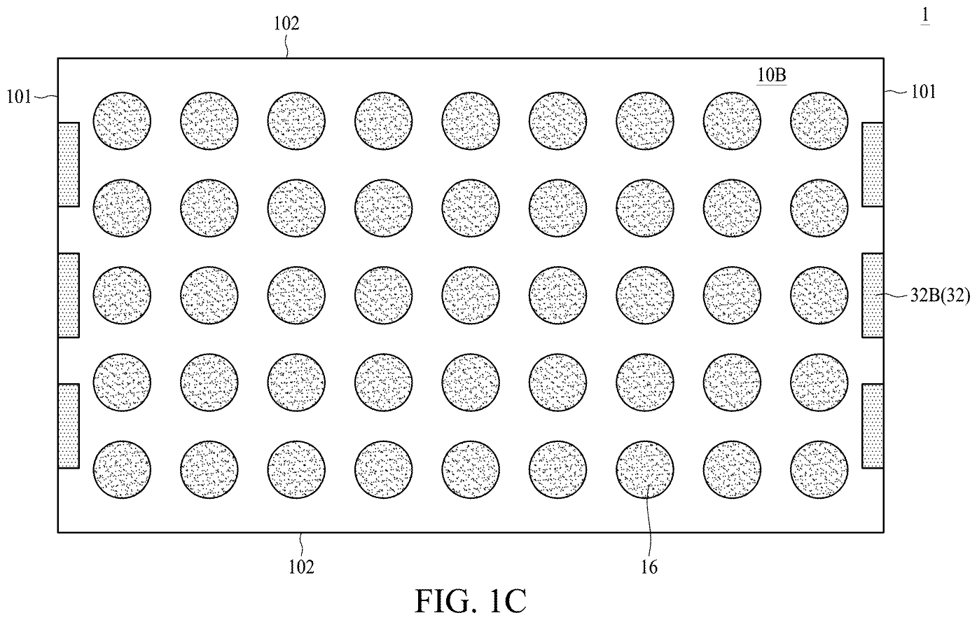

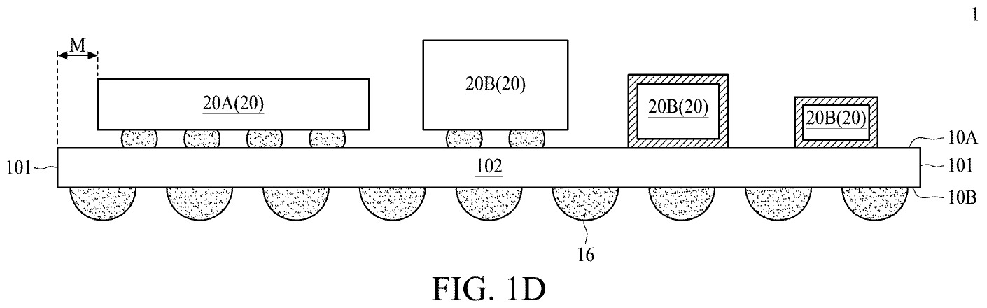

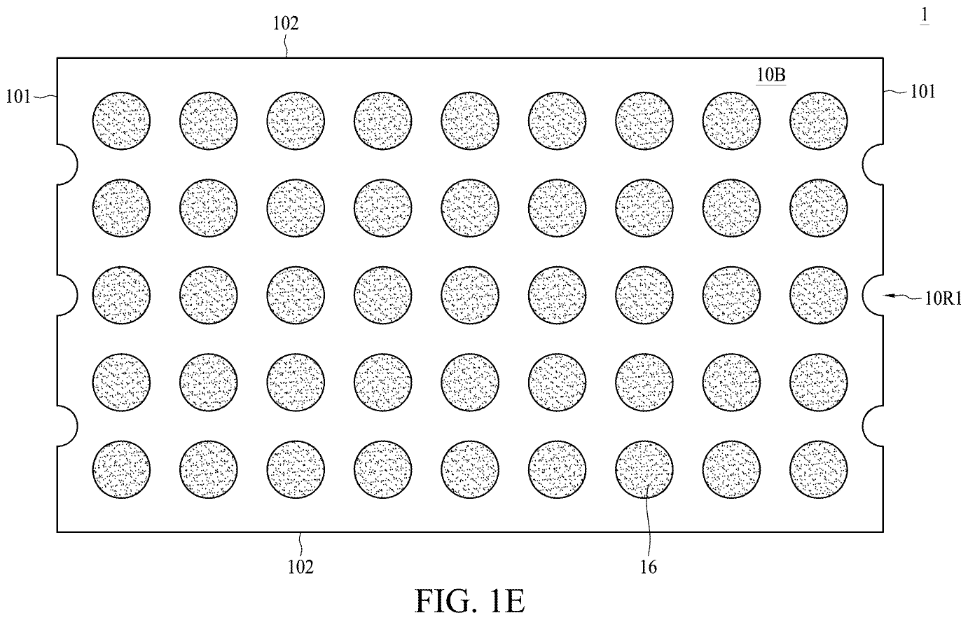

FIG. 1 is a schematic panoramic view of a semiconductor electronic device package 1 in accordance with some embodiments of the present disclosure, FIG. 1A is a schematic side view of a semiconductor device package 1 from a short side in FIG. 1, FIG. 1B is a schematic side view of a semiconductor device package 1 from a long side in FIG. 1, FIG. 1C is a schematic bottom view of a semiconductor device package 1 in accordance with some embodiments of the present disclosure, FIG. 1D is a schematic side view of a semiconductor device package 1 in the absence of an encapsulation layer in accordance with some embodiments of the present disclosure, and FIG. 1E is a schematic bottom view of a semiconductor device package 1 in the absence of an encapsulant layer in accordance with some embodiments of the present disclosure. For the purpose of clarity, some components may not be shown in FIG. 1, FIG. 1A, FIG. 1B, FIG. 1C, FIG. 1D and FIG. 1E. As shown in FIG. 1, FIG. 1A, FIG. 1B, FIG. 1C, FIG. 1D and FIG. 1E, the semiconductor device package 1 includes a substrate 10, one or more semiconductor die 20 and a first encapsulant 30. The substrate 10 includes a first surface 10A, a second surface 10B opposite to the first surface, and a first edge 101 and a second edge 102 connecting the first surface to the second surface 10B. In some embodiments, the substrate 10 may include a rectangular substrate such as a panel, and the first edge 101 is shorter than the second edge 102. The substrate 10 may include a conductive substrate with embedded circuitry to build an electrical connection between the first surface 10A and the second surface 10B.

The semiconductor die 20 is disposed on the first surface 10A of the substrate 10. In some embodiments, the semiconductor die 20 may include an active chip 20A such as a logic chip or a system on chip (SOC), a passive chip 20B such as a resistor, a capacitor, an inductor, or a combination thereof. The semiconductor die 20 may be bonded to the substrate 10 by flip chip (FC) bonding, wire bonding or other suitable techniques, and electrically connected to the circuitry of the substrate 10. The first encapsulant 30 is disposed on the first surface 10A of the substrate 10 and encapsulates the semiconductor die 20. In some embodiments, the first encapsulant 30 may include molding compound such as epoxy-based material (e.g. FR4), resin-based material (e.g. Bismaleimide-Triazine (BT)), Polypropylene (PP)) or other suitable molding materials. In some embodiments, the first encapsulant 30 may further include fillers such as silicon oxide fillers dispensed in the molding material. The first encapsulant 30 includes at least one first lock portion 32 extending from the first surface 10A to the second surface 10B. The first lock portion 32 penetrates through the substrate 10 via the first edge 101, and interlocks with the substrate 10. Accordingly, the first encapsulation 30, the substrate 10 and intervening layer(s) between the first encapsulant 30 and the substrate 10 can be firmly fixed to avoid delamination and crack issues.

In some embodiments, the at least one first lock portion 32 separates the first edge 101 into at least two first segmented edge planes 101P as shown in FIG. 1. The at least one first lock portion 32 may be substantially coplanar with the first edge 101 of the substrate 10. In some embodiments, the first edge 101 includes at least one first recess 10R1 recessed from the first edge 101 as shown in FIG. 1E, and the at least one first lock portion 32 is filled into the at least one first recess 10R1 to interlock with the substrate 10 from the first edge 101. Specifically, the first lock portion 32 may include a first upper portion 32U disposed on the first surface 10A, a first bottom portion 32B disposed on the second surface 10B, and a first latch portion 32L connected to the first upper portion 32U and the first bottom portion 32B and engaged with the first recess 10R1. In some embodiments, the first latch portion 32L includes a substantially semi-cylinder structure, and a portion of the first latch portion 32L is exposed from the first edge 101.

In some embodiments, the first encapsulant 30 may include a plurality of first lock portions 32 as shown in FIG. 1. The first upper portions 32U of the first lock portions 32 can be connected together. The first latch portions 32L of the first lock portions 32 may have substantially the same width or different widths. The first bottom portions 32B of the first lock portions 32 may have substantially the same width or different widths. In some embodiments, at least two adjacent first bottom portions 32B of the first lock portions 32 are separated from each other with a first spacing S1. In some embodiments, the first lock portions 32 may be disposed on one first edge 101, and not disposed on another first edge 101. In some embodiments, the first lock portions 32 are disposed on two opposite first edges 101 of the substrate 10. The first lock portions 32 disposed on two opposite first edges 101 may be arranged symmetrically or asymmetrically. As described, since delamination issue tends to occur on the first edge (short edge) 101, the first lock portions 32 that interlocks with the first edge 101 can alleviate delamination. Accordingly, the margin M between the semiconductor die 20 and the first edge 101 can be shortened as shown in FIG. 1D. In some embodiments, the margin M can be reduced to less than 70 micrometers, or even less than 50 micrometers. In some embodiments, there may not be lock portions disposed on the second edge 102 of the substrate 10 as shown in FIG. 1.

The semiconductor device package 1 may further include a plurality of electrical conductors 16 disposed on second surface 10B of the substrate 10, and electrically connected to the circuitry of the substrate 10. The electrical conductors 16 may include solder balls, solder bumps or the like, and configured to electrically connect the semiconductor die 20 to an external electronic component such as a circuit board.

The semiconductor device packages and manufacturing methods of the present disclosure are not limited to the above-described embodiments, and may be implemented according to other embodiments. To streamline the description and for the convenience of comparison between various embodiments of the present disclosure, similar components of the following embodiments are marked with same numerals, and may not be redundantly described.

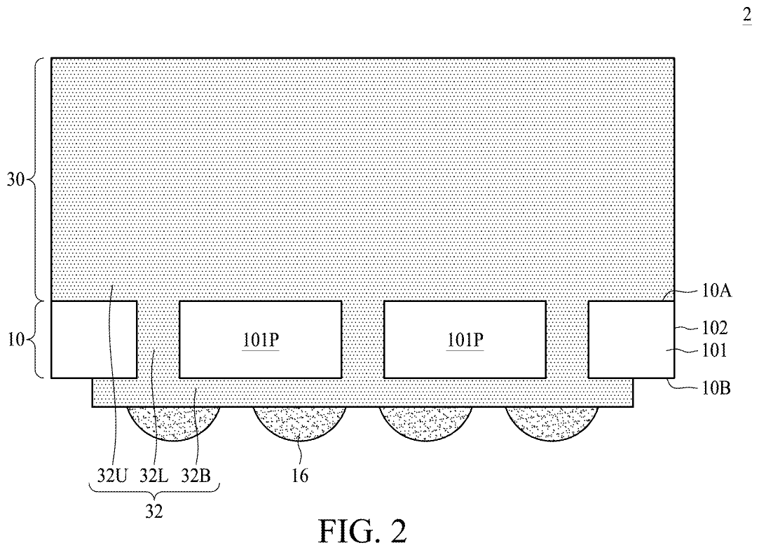

FIG. 2 is a schematic side view of a semiconductor device package 2 in accordance with some embodiments of the present disclosure. As shown in FIG. 2, in contrast to the semiconductor device package 1, at least two adjacent first bottom portions 32B of the first lock portions 32 of the semiconductor device package 2 are connected to each other. For example, all first bottom portions 32B of the first lock portions 32 are connected. The connection of the adjacent first bottom portions 32B can increase the interlock between the first encapsulant 30 and the substrate 10, and thus delamination can be further alleviated.

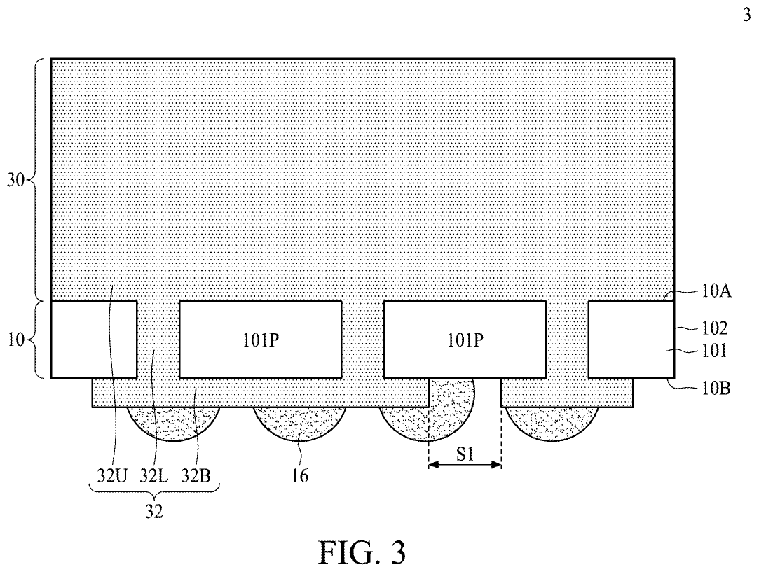

FIG. 3 is a schematic side view of a semiconductor device package 3 in accordance with some embodiments of the present disclosure. As shown in FIG. 3, in contrast to the semiconductor device package 2, some adjacent first bottom portions 32B of the first lock portions 32 of the semiconductor device package 3 are connected to each other, while some first bottom portions 32B of the first lock portions 32 of the semiconductor device package 3 are separated from each other with a first spacing S1.

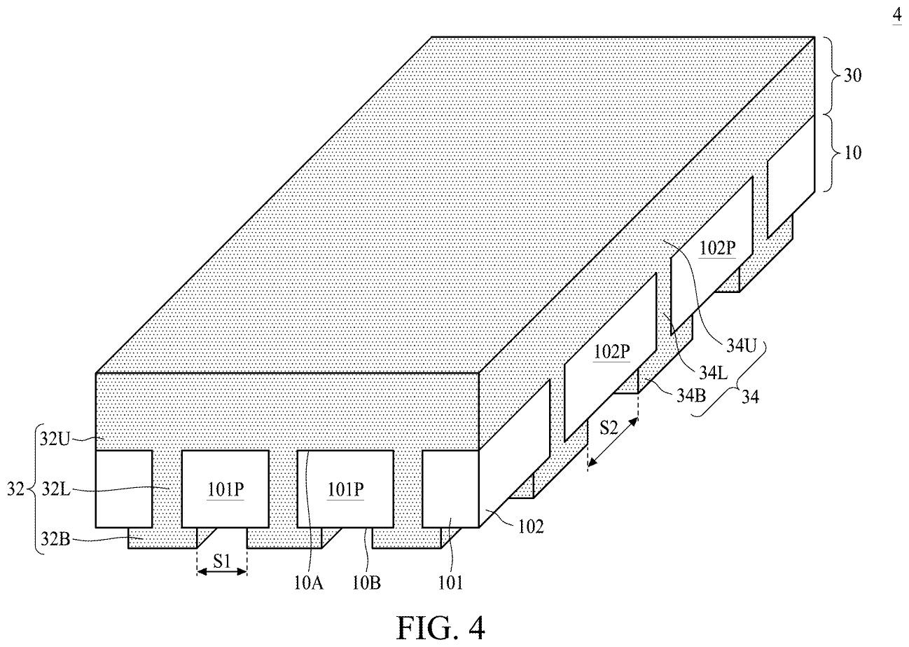

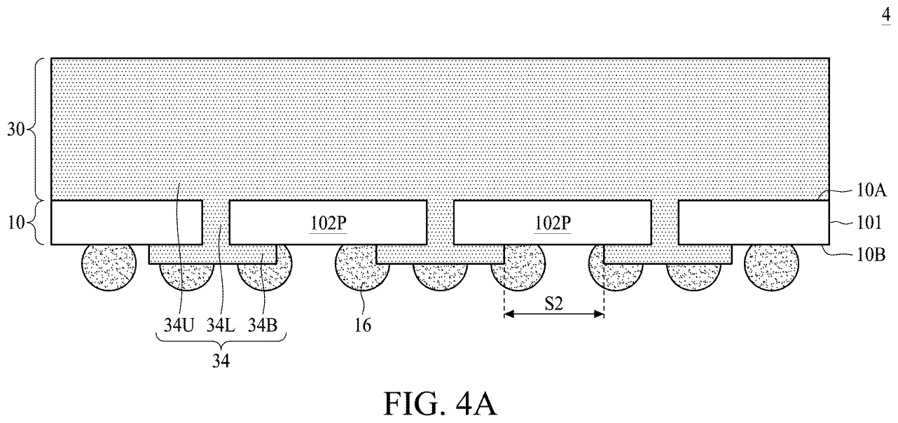

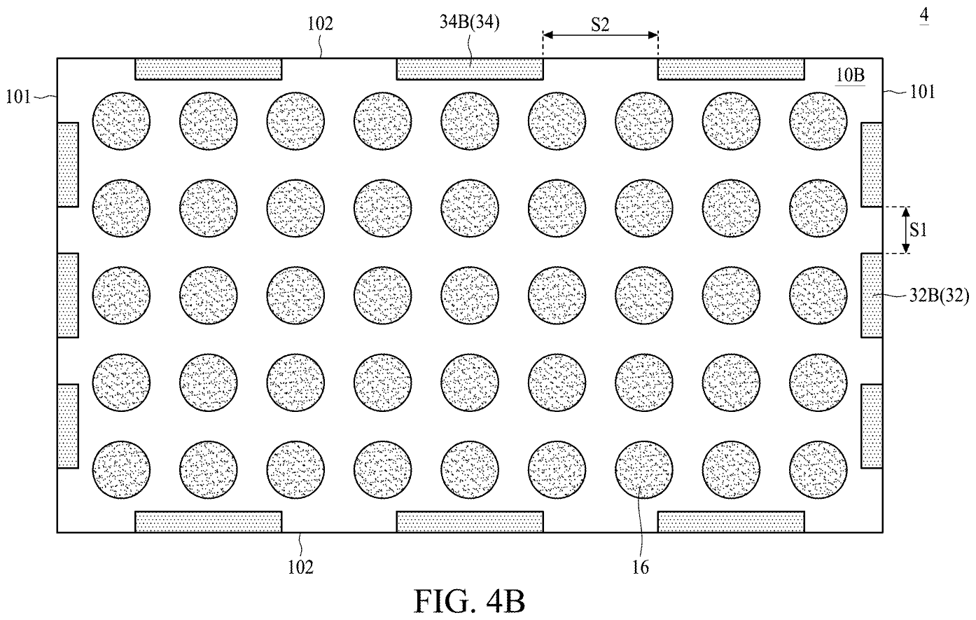

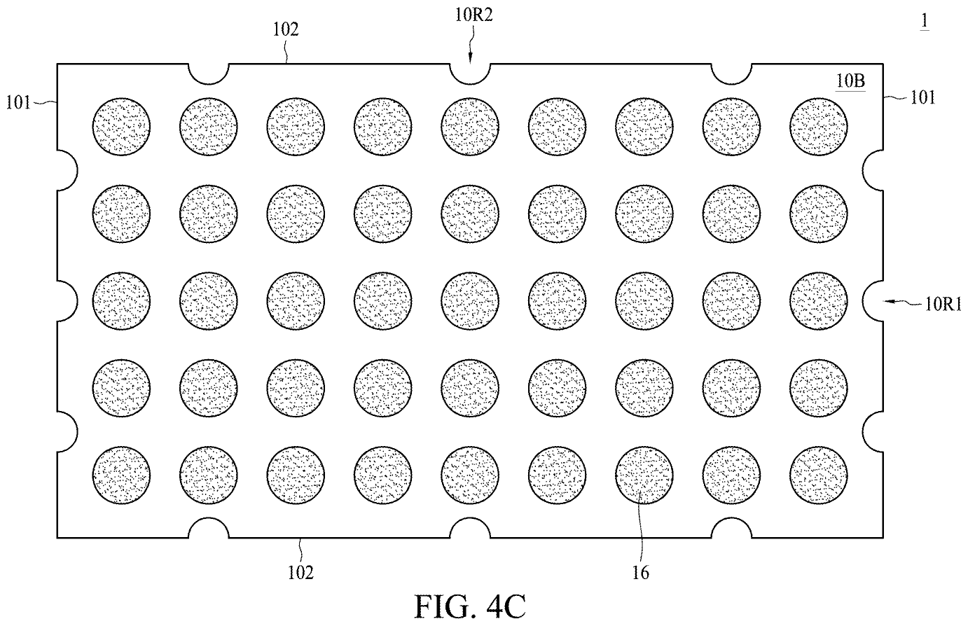

FIG. 4 is a schematic panoramic view of a semiconductor electronic device package 4 in accordance with some embodiments of the present disclosure, FIG. 4A is a schematic side view of a semiconductor device package 4 from a long side in FIG. 4, FIG. 4B is a schematic bottom view of a semiconductor device package 4 in accordance with some embodiments of the present disclosure, and FIG. 4C is a schematic bottom view of a semiconductor device package 4 in the absence of an encapsulant layer in accordance with some embodiments of the present disclosure. As shown in FIG. 4, FIG. 4A, FIG. 4B and FIG. 4C, in contrast to the semiconductor device package 1, in addition to the first lock portions 32 disposed on the first edge 101 of the substrate 10, the first encapsulant 30 further includes a plurality of second lock portions 34 extending from the first surface 10A to the second surface 10B and penetrating through the substrate 10 through the second edge 102. In some embodiments, the second lock portions 34 separate the second edge 102 into a plurality of segmented edge planes 102P. The second lock portions 34 may be substantially coplanar with the second edge 102 of the substrate 10. In some embodiments, the second edge 102 includes a plurality of second recesses 10R2 recessed from the second edge 102 as shown in FIG. 4C, and the second lock portions 34 are filled into the second recesses 10R2 respectively to interlock with the substrate 10 from the second edge 102. Specifically, the second lock portion 34 may include a second upper portion 34U disposed on the first surface 10A, a second bottom portion 34B disposed on the second surface 10B, and a second latch portion 34L connected to the second upper portion 34U and the second bottom portion 34B and engaged with the second recess 10R2. In some embodiments, the second latch portion 34L includes a substantially semi-cylinder structure, and a portion of the second latch portion 34L is exposed from the second edge 102. The second latch portions 34L of the second lock portions 34 may have substantially the same width or different widths. The second bottom portions 34B of the second lock portions 34 may have substantially the same width or different widths. In some embodiments, at least two adjacent second bottom portions 34B of the second lock portions 34 are separated from each other with a second spacing S2. In some embodiments, the second lock portions 34 may be disposed on one second edge 102, and not disposed on another second edge 102. In some embodiments, the second lock portions 34 are disposed on two opposite second edges 102 of the substrate 10. The second lock portions 34 disposed on two opposite second edges 102 may be arranged symmetrically or asymmetrically. In some embodiments, there may not be lock portions disposed on the first edge 101 of the substrate 10. In some embodiments, the second spacing S2 may be larger than the first spacing S1.

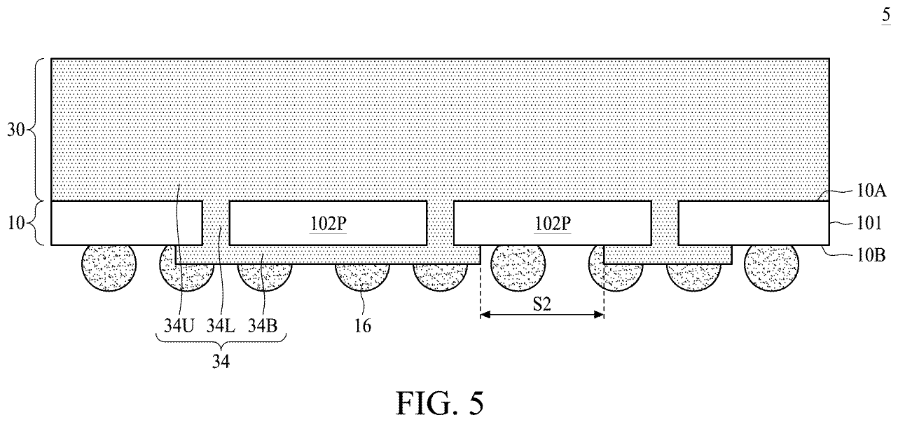

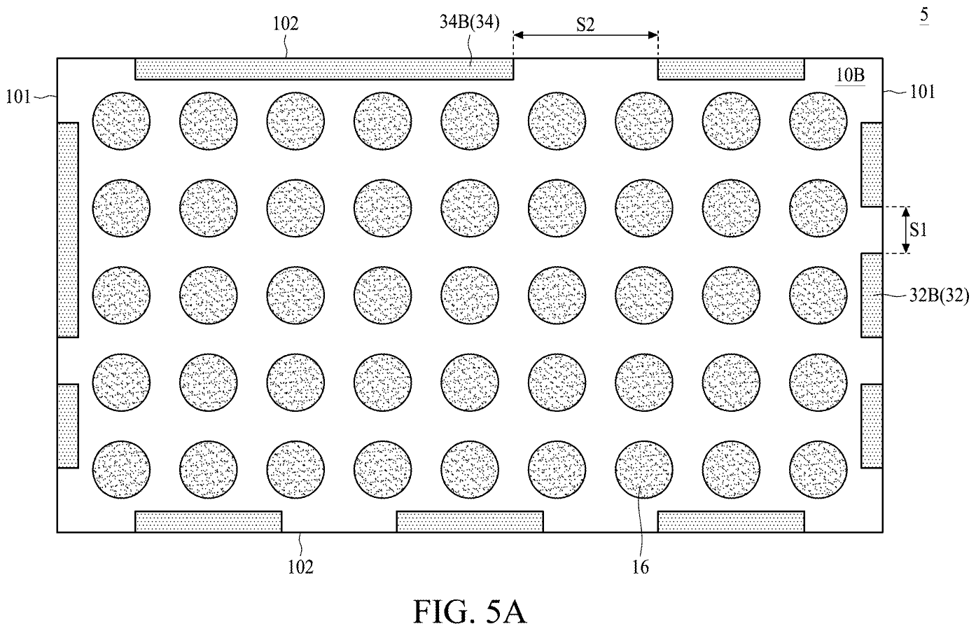

FIG. 5 is a schematic side view of a semiconductor device package 5 in accordance with some embodiments of the present disclosure, and FIG. 5A is a schematic bottom view of a semiconductor device package 5 in accordance with some embodiments of the present disclosure. As shown in FIG. 5 and FIG. 5A, in contrast to the semiconductor device package 4, at least two adjacent second bottom portions 34B of the second lock portions 34 of the semiconductor device package 5 are connected to each other. For example, some adjacent second bottom portions 34B of the second lock portions 34 of the semiconductor device package 5 are connected to each other, while some second bottom portions 34B of the second lock portions 34 of the semiconductor device package 5 are separated from each other with a second spacing S2. The first lock portions 32 disposed on two opposite first edges 101 may be arranged asymmetrically, and the second lock portions 34 disposed on two opposite second edges 102 may be arranged asymmetrically. The connection of the adjacent second bottom portions 34B can increase the interlock between the first encapsulant 30 and the substrate 10, and thus delamination can be avoided.

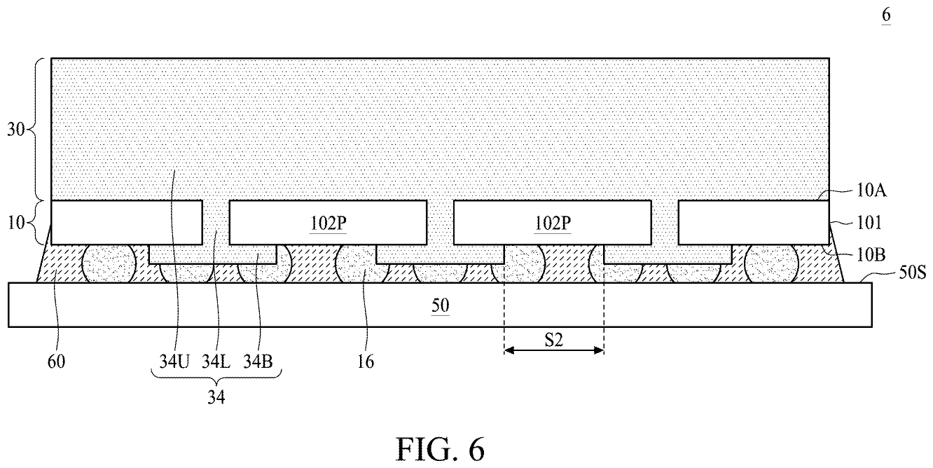

FIG. 6 is a schematic side view of a semiconductor device package 6 from a long side in accordance with some embodiments of the present disclosure. As shown in FIG. 6, the semiconductor device package 6 may further include a circuit board 50 and a second encapsulant 60. The circuit board 50 may include a printed circuit board (PCB) 50 or the like disposed under the second surface 10B of the substrate 10. The circuit board 50 includes a surface 50S facing the second surface 10B of the substrate 10. The second encapsulant 60 is disposed at least between the second surface 10B of the substrate 10 and the surface 50S of the circuit board 50 and encapsulates the electrical conductors 16. In some embodiments, the second encapsulant 60 may include an underfill layer. The second encapsulant 60 may climb up a portion of the first edges 101 and the second edges 102 of the substrate 10. The second encapsulant 60 may include fillers such as silicon oxide fillers dispensed in the underfill layer. The second spacing S2 may be larger than three times the size of the filler such that the flow-able encapsulating material of the underfill layer and the fillers can flow through the second spacing S2 to encapsulate the electrical conductors 16. The flow-able encapsulating material may be baked to form the second encapsulant 60. The second encapsulant 60 may be filled in the second spacing S2 and the first spacing S1 as shown in FIG. 1-FIG. 5, and engaged with the first bottom portions 32B and the second bottom portions 34B to further enhance robustness of the semiconductor device package 6.

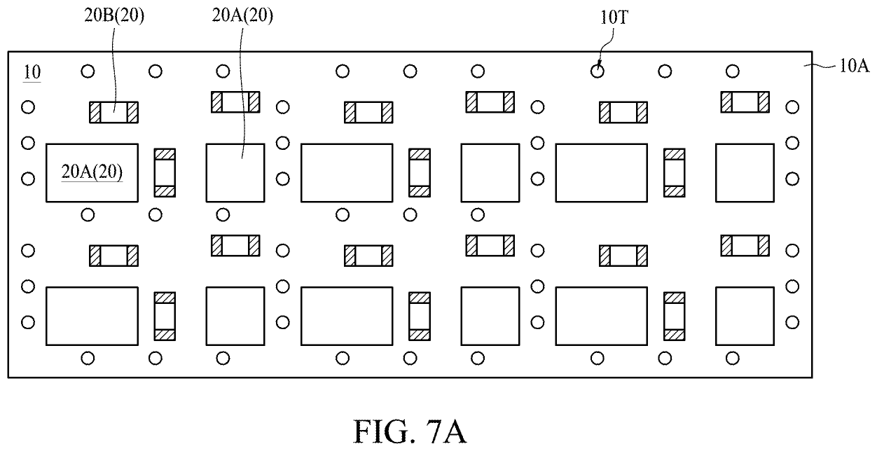

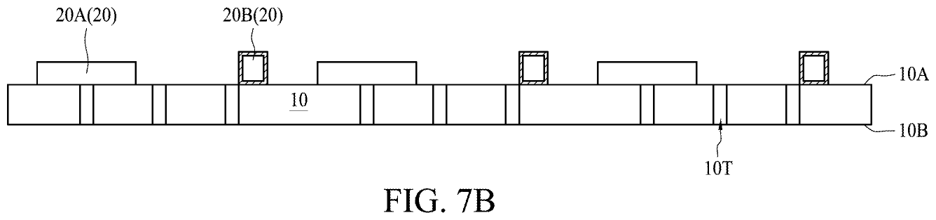

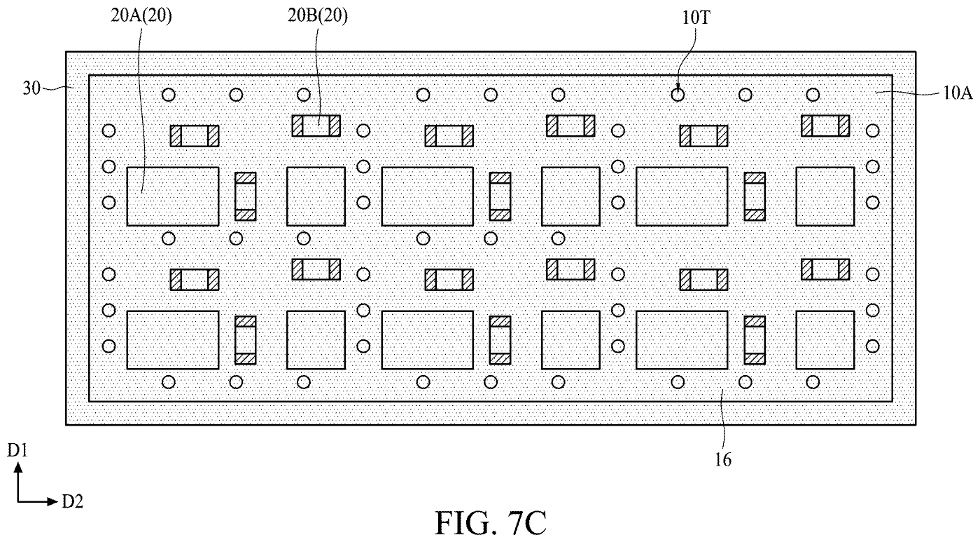

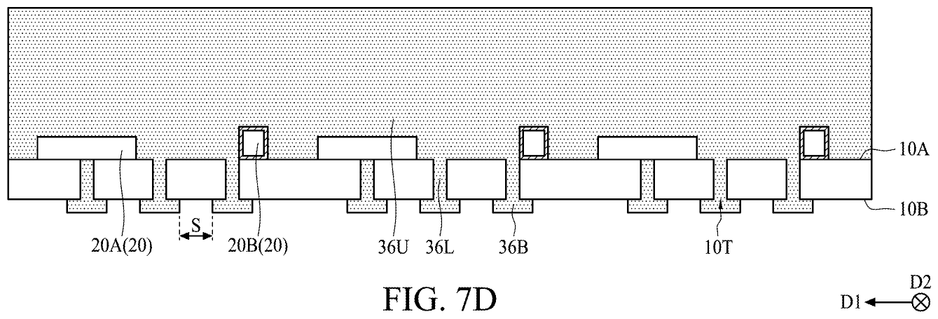

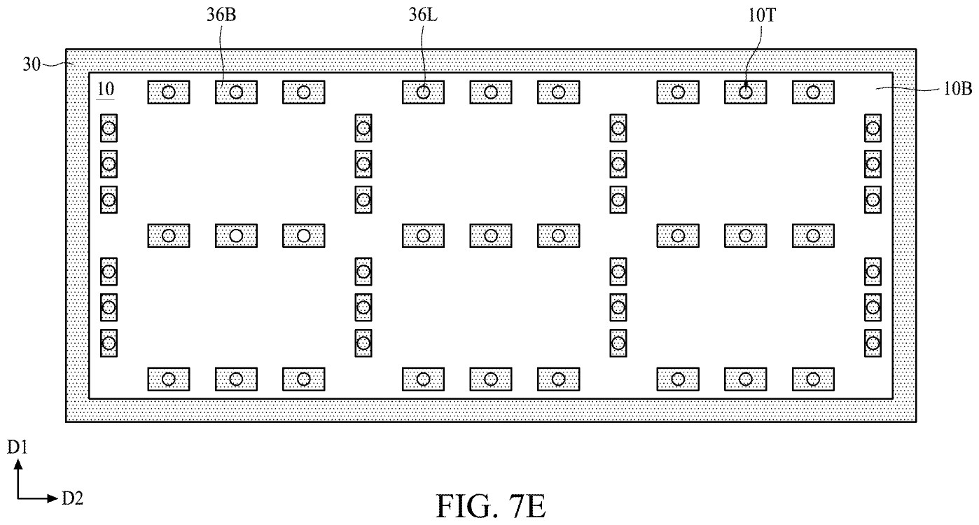

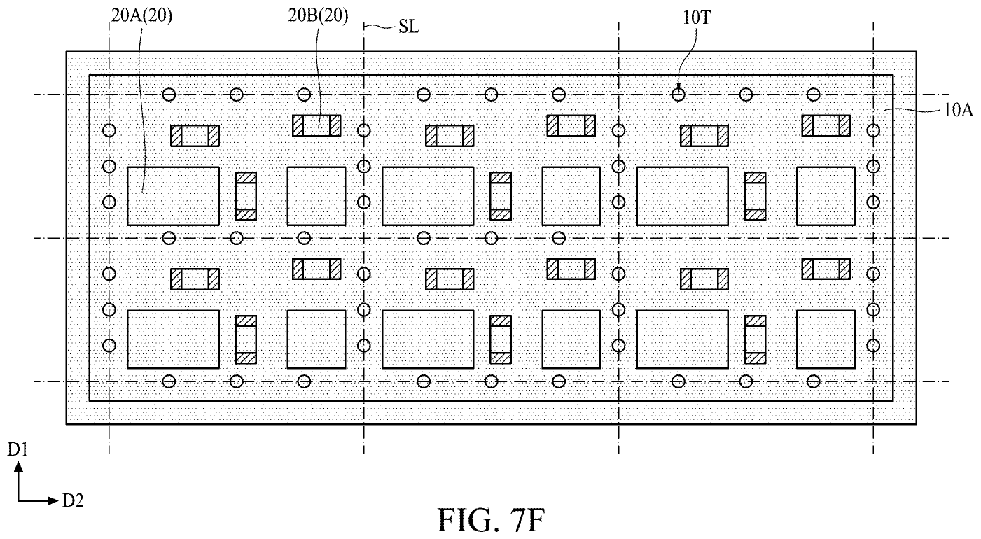

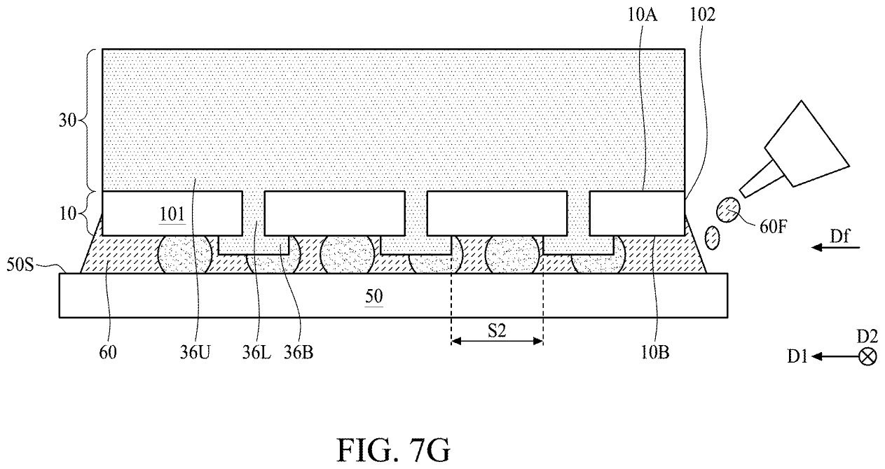

FIG.7A, FIG.7B, FIG. 7C, FIG. 7D, FIG. 7E, FIG. 7F and FIG. 7G illustrate operations of manufacturing a semiconductor device package in accordance with some embodiments of the present disclosure, where FIG. 7A, FIG. 7C and FIG. 7F are schematic top views, FIG. 7B, FIG. 7D and FIG. 7G are cross-sectional views and FIG. 7E is a bottom view. As shown in FIG. 7A and FIG. 7B, a substrate 10 is provided. The substrate 10 includes a first surface 10A, a second surface 10B opposite to the first surface 10A, and a plurality of through holes 10T. A plurality of semiconductor dies 20 including active chips 20A, passive chips 20B or a combination thereof are mounted on the substrate 10.

As shown in FIG. 7C, FIG. 7D and FIG. 7E, a first encapsulant 30 is formed on the substrate 10. The first encapsulant 30 may be formed by molding technique. For example, a flow-able encapsulating material with fillers is introduced in a mold chase, and then baked to form the first encapsulant 30. The first encapsulant 30 includes an upper portion 36U on the first surface 10A, a plurality of latch portions 36L in the through holes 10T, and a plurality of bottom portions 36B on the second surface 10B. The bottom portions 36B are arranged along an arrangement direction, and adjacent bottom portions are separated with a spacing S. In some embodiments, the bottom portions 36B are arranged along an arrangement direction D1, another arrangement direction D2, or both the arrangement directions D1 and D2.

As shown in FIG. 7F, the first encapsulant 30 and the substrate 10 are singulated by e.g., dicing, sawing or the like along a scribe line SL traversing the through holes 10T along the arrangement directions D1 and D2 to form a plurality of semiconductor device packages.

As shown in FIG. 7G, the singulated substrate 10 is a rectangular substrate having a first edge 101 and a second edge 102, where the first edge 101 is shorter than the second edge 102. The first edge 101 is substantially parallel to the arrangement direction D1, and the second edge 102 is substantially parallel to the arrangement direction D2. A plurality of electrical conductors 16 are formed on second surface 10B of the substrate 10. The substrate 10 is then bonded to a circuit board 50 with the electrical conductors 16. A flow-able encapsulating material 60F with fillers through the spacing S of the bottom portions 36B along a flow direction Df substantially perpendicular to the arrangement direction D1 or D2 to form a second encapsulant 60 on the second surface 10B of the substrate 10. In some embodiments, the flow-able encapsulating material 60F is introduced from the second edge (long edge) 102 of the substrate 10, and the flow direction Df is substantially perpendicular to the arrangement direction D2 such that the travel distance of the flow-able encapsulating material 60F is shorter. In some embodiments, the spacing S between the bottom portions 36B disposed on the second edge 102 of the substrate 10 is larger than three times the size of the filler of the flow-able encapsulating material 60F such that the fillers can smoothly passing through the spacing S.

In some embodiments of the present disclosure, the semiconductor device package includes lock portions that extend from the top surface, one or more edges to the bottom surface to firmly interlock with the substrate. As a result, delamination can be alleviated, and the margin between the edge of the substrate and the semiconductor die can be reduced. According miniaturization of semiconductor device package can be realized.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A semiconductor device package, comprising:
a substrate including a first surface, a second surface opposite to the first surface, and a first edge and a second edge connecting the first surface to the second surface, wherein the first edge is shorter than the second edge;
a semiconductor die disposed on the first surface of the substrate; and
a first encapsulant disposed on the first surface of the substrate and encapsulating the semiconductor die, wherein the first encapsulant comprises at least one first lock portion extending from the first surface to the second surface and penetrating through the substrate via the first edge.

2. The semiconductor device package of claim 1, wherein the at least one first lock portion separates the first edge into at least two first segmented edge planes.

3. The semiconductor device package of claim 1, wherein the first edge includes at least one first recess recessed from the first edge, and the at least one first lock portion is filled into the at least one first recess.

4. The semiconductor device package of claim 3, wherein the first lock portion comprises a first upper portion disposed on the first surface, a first bottom portion disposed on the second surface, and a first latch portion connected to the first upper portion and the first bottom portion, and engaged with the first recess.

5. The semiconductor device package of claim 4, wherein the first encapsulant comprises a plurality of the first lock portions.

6. The semiconductor device package of claim 5, wherein at least two adjacent first bottom portions of the first lock portions are separated from each other with a first spacing.

7. The semiconductor device package of claim 5, wherein at least two adjacent first bottom portions of the first lock portions are connected to each other.

8. The semiconductor device package of claim 6, wherein the first encapsulant further comprises a plurality of second lock portions extending from the first surface to the second surface and penetrating through the substrate through the second edge.

9. The semiconductor device package of claim 8, wherein the second lock portions separate the second edge into a plurality of segmented edge planes.

10. The semiconductor device package of claim 8, wherein the second edge includes a plurality of second recesses recessed from the second edge, and the second lock portions are filled into the second recesses respectively.

11. The semiconductor device package of claim 10, wherein the second lock portions each comprises a second upper portion disposed on the first surface, a second bottom portion disposed on the second surface, and a second latch portion connected to the second upper portion and the second bottom portion, and engaged with the second recess.

12. The semiconductor device package of claim 11, wherein at least two adjacent second bottom portions of the second lock portions are separated from each other with a second spacing.

13. The semiconductor device package of claim 12, wherein the second spacing is larger than the first spacing.

14. The semiconductor device package of claim 12, further comprising:
a circuit board disposed under the second surface of the substrate;
a plurality of electrical conductors disposed between and electrically connected to the substrate and the circuit board; and
a second encapsulant disposed at least between the substrate and the circuit board and encapsulating the electrical conductors.

15. The semiconductor device package of claim 14, wherein the second encapsulant comprises a plurality of fillers, and the second spacing is substantially larger than three times a size of the filler.

16. A semiconductor device package, comprising:
a substrate including a first surface, a second surface opposite to the first surface, and an edge connecting the first surface to the second surface;
a semiconductor die disposed on the first surface of the substrate;
a first encapsulant disposed on the first surface of the substrate and encapsulating the semiconductor die, wherein the first encapsulant comprises a plurality of lock portions each including an upper portion disposed on the first surface, a bottom portion disposed on the second surface, and a latch portion connected to the upper portion and the bottom portion and penetrating through the edge, wherein two adjacent bottom portions of the latch portions are separated with a spacing;
a circuit board disposed under the substrate, wherein the circuit board includes a surface facing the second surface of the substrate; and
a second encapsulant disposed between the surface of the circuit board and the second surface of the substrate, and filling in the spacing.

17. The semiconductor device package of claim 16, further comprising a plurality of electrical conductors disposed between and electrically connected to the substrate and the circuit board, and encapsulated by the second encapsulant.

18. The semiconductor device package of claim 16, wherein the second encapsulant comprises an underfill layer comprising a plurality of fillers, and the spacing is substantially larger than three times a size of the filler.

19. A method of manufacturing a semiconductor device package, comprising:
providing a substrate including a first surface, a second surface opposite to the first surface, and a plurality of through holes;
forming a first encapsulant on the substrate, wherein the first encapsulant comprises an upper portion on the first surface, a plurality of latch portions in the through holes, and a plurality of bottom portions on the second surface, and wherein the bottom portions are arranged along an arrangement direction, and adjacent bottom portions are separated with a spacing; and
introducing a flow-able encapsulating material with fillers through the spacing of the bottom portions along a flow direction substantially perpendicular to the arrangement direction to form a second encapsulant on the second surface of the substrate.

20. The method of claim 19, further comprising singulating the first encapsulant and the substrate along a scribe line traversing the through holes along the arrangement direction.
